(19) United States
(12) Patent Application Publication
(10) Pub. No.: US 2002/0084429 A1
(43) Pub. Date: Jul. 4, 2002

(54) Electron-beam patterning of functionalized self-assembled monolayers

(76) Inventors: Harold G. Craighead, Ithaca, NY (US); Cindy K. Harnett, Livermore, CA (US); K. M. Satyalakshmi, Ithaca, NY (US)

Correspondence Address: SCHWEGMAN, LUNDBERG, WOESSNER & KLUTH, P.A., P.O. BOX 2938, MINNEAPOLIS, MN, 55402, US

(21) Appl. No.: 09/981,768

(22) Filed: Oct. 17, 2001

Related U.S. Application Data
(60) Provisional application No. 60/241,024, filed on Oct. 17, 2000.

(51) Int. Cl. H01J 37/08

(52) U.S. Cl. 250/492.22

(57) ABSTRACT

The present invention provides a method of patterning a self-assembled monolayer (SAM) on a substrate comprising employing low electron-beam lithography to selectively deactivate functional groups at the surface of said SAM in a preselected area of said surface, wherein said functional groups bind to a target substance but said deactivated functional groups do not, so that the surface of said SAM can be contacted with said target substance so that the target substance binds to said functional groups but does not bind to said deactivated groups in said preselected area, to yield a pattern of said target substance on said surface.

### CROSS REFERENCE TO RELATED APPLICATION

This application claims the benefit of U.S. Provisional Application Serial No. 60/241,024 filed Oct. 17, 2000, under 35 U.S.C. 119(e).

### GOVERNMENT GRANT

This invention was made with Government support from the Office of Naval Research (ONR) under Contract No. N00014-97-1-0779 and the Advanced Research Projects Agency (ARPA) under Contract No. MDA940-95-C-2111. The Government has certain rights in the invention.

### BACKGROUND OF THE INVENTION

Self-assembled monolayer (SAM) surfaces have been intensively studied as surface coatings for nanofabrication techniques because they can be tailored to promote or resist the adhesion of specific substances at the molecular level. Methods of patterning self-assembled monolayers include UV lithography (C. S. Dulcey et al., Science, 252, 551 (1991)), microcontact printing (Y. Xia et al., Angew. Chem. Int. Ed. Eng., 37, 550 (1998); L. Yan et al., JACS, 120, 6179 (1998)), scanned probe lithography, and electron-beam lithography. See, respectively, F. K. Perkins et al., Appl. Phys. Lett., 68, 550 (1996) and M. J. Lercel et al., J. Vac. Sci. Technol. B, 13, 1139 (1995). Electron-beam lithography can produce high resolution, precisely aligned patterns and does not require direct substrate contact.

Applications of patterned reactive monolayers in device fabrication include metal deposition and plating for conductive paths, deposition of semiconductor particles for photonic devices and patterning carbon nanotubes for electronic devices. See, for example, S. L. Brandow et al., J. Electrochem. Soc., 114, 3425 (1997); T. Vossmeyer et al., J. Appl. Phys., 84, 3064 (1998); J. Liu et al., Chem. Phys. Lett., 303, 125 (1999), respectively. Examples of materials that have been selectively deposited on the hydrophilic surface of patterned amine monolayers include nanoparticles, metals, fluorescent molecules, and biological cells. See, T. Vossmeyer et al., J. Appl. Phys., 84, 3664 (1998) and C. S. Dulcey et al., cited above.

SAMs have already seen commercial success in biotechnology. See, S. Fodor et al., Science, 251, 767 (1991) and D. R. Basch et al., Proc. IEEE, 85, 672 (1997). Biological applications for cell-based experiments include tissue engineering, such as using monolayer patterning for control of neuron adhesion, patterning of single cell adhesive regions for studying programmed cell death, and controlled placement of multiple cell types to study cell interactions. For example, see, respectively, C. D. James et al., IEEE Trans. Biomed. Eng., 47, 17 (2000); C. S. Chen et al., Science 276, 1425 (1997) and S. N. Bhatia et al., J. Biomed. Mater. Res., 34, 189 (1997). Biological applications on the molecular scale include biosensors, such as antibody assay systems created by tethering antibodies to monolayers at known positions and controlled wetting of patterned monolayer surfaces to create microfluidic reaction volumes. See, respectively, D. J. Pitchard et al., Anal. Chem., 67, 3605 (1995); H. Gau et al., Science, 283, 46 (1999).

Therefore, a need exists for methods for high-resolution patterning of biological materials that can lead to further miniaturization of multi-analyte biological assays, and better control over the chemical environment of surface-bound biologicals, such as proteins and cells. There is a further need for precise pattern registration to enable the creation of aligned multi-chemical patterns and well-defined active areas on nanoelectromechanical sensors.

### SUMMARY OF THE INVENTION

The present invention provides a method of patterning a self-assembled monolayer (SAM) on a substrate comprising employing low electron-beam lithography to selectively deactivate functional groups at the surface of said SAM in a preselected area of said surface, wherein said functional groups bind to a target substance but said deactivated functional groups do not. Thus, the method further comprises patterning a SAM by contacting said surface of said SAM with said target substance under conditions so that the target substance binds to said functional groups but does not bind to said deactivated groups in said preselected area, to yield a pattern of said target substance on said surface. The present invention also provides substrates, such as chips, wafers and the like, comprising said patterned SAMs, preferably comprising said bound target substance on the surface thereof. In one preferred embodiment of the invention, said functional groups comprise amino groups, e.g., said SAM comprises organoamines, such as alkoxysilyl-organoamines, wherein the silyl group binds to the substrate surface, exposing the amino groups at the SAM surface. Low electron-beam lithography is employed to deactivate, i.e., to remove the amino groups, thus leaving the SAM unable to bind to functional groups in a preselected area of the SAM surface. Thus, when a target substance comprising functional groups that can react with amino groups is contacted with the patterned SAM surface, it will bind only to the remaining amino groups, while not binding to areas of the surface where the amino groups have been deleted, or otherwise altered, so they are nonreactive with the target substance. For example, the target substance can comprise a functional group that is normally reactive with amino groups, such as an aldehyde group, a carboxylic acid group, an activated carboxylic acid group or a mixture thereof. Such functional groups are present in, or can readily be introduced into, many substances such as synthetic organic polymers, and biologicals, such as nucleic acids, amino acids and polypeptides, e.g., DNA, RNA, antibodies, enzymes, cytokines, receptors, and the like.

Thus, patterned functionalized self-assembled monolayers can function as templates for the deposition and patterning of a wide variety of materials on substrate surfaces, such as silicon surfaces, with extremely high resolution, preferably about sub-100 nm, preferably about 5-75 nm. On ultrathin (1-2 nm) monolayers, lower electron-beam energies (<5 keV) produce higher resolution patterns than high-energy beams. Auger electron spectroscopy indicates that low-energy electron exposure primarily damages amine groups on ω-aminoalkylsilanes. At 1 keV, a dose of 40 μC/cm² is required to make the patterns observable by lateral force microscopy. Features as small as 80 nm were exposed at 2 keV on amino group-containing monolayers. After exposure, a wide variety of target substances, including palladium colloids and aldehyde- and protein-coated polystyrene fluorescent spheres adhered only to unexposed areas of the monolayers.

### BRIEF DESCRIPTION OF THE FIGURES

FIG. 1 includes three photocopies of lateral force microscopy (LFM) images of dose bars exposed at: (a) 1 keV, (b) 5 keV, and (c) 10 keV. Patterns consist of 1 μm bars formed with electron doses of 100, 200, 300, 400, and 500 μC/cm² from left to right. FIG. 1(d) is a graph depicting a vertical average of the LFM signal, with sharper corners as energy decreases.

FIG. 2 is a graph depicting the area under nitrogen Auger peak versus electron exposure for APTS (∘) and PEDA (♦) monolayers. Electron dose is from the Auger instrument. At 10 keV electron exposure decreases the nitrogen signal to undetectable levels in APTS at 150 μC/cm² and in PEDA at 300 μC/cm². The structures of these compounds are shown in the inserts.

FIG. 3(a) is a photocopy of the scanning electron image of Pd colloids attached to PEDA monolayer patterned at 1 keV, 500 μC/cm². Exposed areas are dark rectangles.

FIG. 3(b) is a photocopy of an auger element map of palladium signal in the same area, showing more Pd (light areas) in unexposed regions.

FIG. 3(c) is a photocopy of an optical fluorescence micrograph of APTS exposed at 1 keV, 400 μC/cm², then functionalized with 20 nm aldehyde-modified polystyrene spheres (light areas).

FIG. 3(d) is a photocopy of an optical fluorescence of APTS exposed at 1 keV, 300 μC/cm², then functionalized with 40 nm NeutrAvidin protein-coated polystyrene spheres (light areas).

FIG. 4 is a photocopy of a lateral force microscopy image of 80 nm diam. dots written in PEDA at 2 keV with a dose of 5 fC/dot.

### DETAILED DESCRIPTION OF THE INVENTION

Self-Assembled Organic Monolayers

SAMs useful in the practice of the present invention can be formed from molecules having a trihalosilyl group, such as SiCl₃ or a [(C₁-C₄)alkoxy]Si group at or near one end of a hydrocarbon chain and a wide variety of functional groups, such as one or more, preferably 1-3, halo, CN, NH₂, SC(O)CH₃, SCN, epoxy, vinyl, CO₂[(C₁-C₄)alkyl], OH, CO₂H, SO₃H, CO₂CF₃ at the other end of the chain, which can vary in length from about 2-22 carbon atoms, preferably about 5-20 and most preferably about 10-18 carbon atoms. Thiols and other sulfur-containing groups can be used to anchor a hydrocarbon chain to metals. The hydrocarbon chain separating the silyl group from the functional group can also include aryl group(s) such as a phenyl group, unsaturation, or be interrupted by NH, O, S, CH═CH, —C≡C— and the like. In cases wherein multiple functional groups are involved, electron-beam lithography can be used to selectively deactivate, or modify the reactivity of the SAM component, as well as to completely deactivate the region of the monolayer component near the surface. For example, the beam may destroy one functional group while leaving a second one on the same molecule intact, and thus create a SAM patterned with areas of varying reactivity or binding affinity toward a given population of target substances.

The SAM forms in a spontaneous, self-assembling process during which one end of the SAM component molecule end bonds covalently, by complexation or by ionic association to the substrate surface, as by condensation with an oxide or hydroxide-bearing surface of a substrate such as silicon, glass, or any material capable of forming an oxide surface. Additionally, Si—O—Si bonds can form between the individual molecules in the monolayer providing additional stability.

Efforts have been made to describe the arrangement and concentration of functional groups on the SAM surface. It is reasonably considered that the long-chain hydrocarbons project at a uniform, near-normal angle to the substrate, presenting an ordered close-packed two-dimensional array to their surroundings.

The surface to which the SAM bonds can be a bulk oxide, such as glass, sapphire, etc., or the native oxide on, for example, Si, Ge, Ti, Al or other metals. The covalent bonding is more rugged than in related structures such as Langinuir-Blodgett films, allowing the SAM to survive exposure to fairly aggressive conditions during subsequent processing. Such processing can include in situ installation and interconversion of exposed surface functionalities. For example, by creating appropriately functionalized SAMs, metal oxides can be induced to form on the SAMs from organometallic or aqueous salt solutions. See, U.S. Pat. No. 3,352,485.

Low-Energy Electron-Beam Lithography

The general techniques and apparatus for conducting low-energy electron-beam lithography are disclosed by Utsumi (U.S. Pat. No. 5,831,272), and its use to etch patterns in a thin resist on materials such as silicon.

The system of the Utsumi patent transfers a pattern on a mask formed by a thinned membrane, typically of a thickness of about 0.5 microns, in a wafer, typically of monocrystalline silicon, to an ultrathin electron-beam sensitive resist, typically about 0.1 micron thick, on a silicon substrate. The mask is a stencil mask in close proximity to the substrate, typically spaced apart no more than a few tens of microns, such as 50 microns. The electron beam is accelerated by a low voltage, typically about 2 keV, and the beam current is relatively small, for example, about three microamperes. The electron beam is deflected perpendicular to the mask in a scanning pattern that may be either a raster or a vector scan or interlaced scan.

From an apparatus aspect, the Utsumi patent discloses an electron-beam lithography system for patterning a resist on a semiconductor substrate. The system comprises a source of an electron beam, a mask positioned in the path of the electron beam, and means for supporting a resist-covered substrate in the path of the electron beam and the mask. The system is characterized in that the electron-beam sensitive resist is ultrathin, the voltage accelerating the beam is sufficiently low that the proximity effect is insignificant, the power of the beam is sufficiently low that heating of mask, resist, and substrate is also insignificant, and the density of electrons in the beam is sufficiently low that space charge effects are insignificant. Such systems are useful for practice of the present method, wherein the “resist” is replaced by a SAM.

From a method aspect, the Utsumi patent is directed to a process of patterning a resist-covered silicon substrate in the manufacture of silicon-integrated circuits. The process comprises the steps of: positioning in an electron-beam apparatus a silicon substrate having one surface on which there is a layer of an electron-beam sensitive resist to be patterned having a thickness in the range of about 0.03 to 0.3 micron; positioning a patterned mask adjacent the resist-layered surface of the silicon substrate spaced apart therefrom a distance of between about 100 to 300 microns; sweeping an electron beam over the patterned mask, substantially normal to the mask, at an accelerating voltage in the range of about 1 to 4 keV and at a beam current up to about 20 microamperes, whereby there is patterned the resist with insignificant heating of the mask. This methodology has been found to be adaptable to pattern SAMs in accord with the present invention.

Target Substance

The target substance or substances can comprise any element (e.g., metal), compound (e.g., nucleic acid, amino acid, peptide, protein, enzyme, receptor, antibody) or composition (e.g., functionalized microspheres, liposomes, nanoparticles, cells, cell fragments or the like) that can bind with sufficient selectivity to the surface of the SAM following lithography thereof, so that it can be patterned on the modified SAM, binding to areas comprising retained functional groups while not binding to areas in which the terminal functional group has been deactivated or destroyed. As used herein, the terms “binds to” a target or SAM or does “not bind to” a target or SAM, are used not in an absolute sense, to mean 100% bonding vs. 0% bonding, but rather as those terms would be recognized by the art and as used in the context of the working examples hereinbelow. In other words, the binding of a given target sequence by a given SAM vs. a lithographed SAM is selective to the extent that the resultant pattern can be recognized by methods such as visual or electron microscopy, detection of fluorescence and the like, as disclosed below.

The target substance may comprise a functional group reactive with a terminal functional group at the surface of the SAM, that is native to the target substance, e.g., as an aldehyde or acetal group is to a sugar, or a CO₂H or NH₂ group is to an amino acid, or the target substance may be modified to introduce a suitable functional group, e.g., by introducing avidin or biotin groups into a molecule to create a binding pair, or by introducing functional groups into an organic polymer such as a polymeric hydrocarbon or cellulose. The reaction and/or binding between the target substance and the SAM may be spontaneous upon contact of the two, or may be catalyzed or otherwise induced during the contact between the two materials.

The invention will be further described by reference to the following detailed examples.

### EXAMPLE 1

### Low-Energy Electron-Beam Processing of Amine-Terminated 2-amino-propyltriethoxysilane (APTS) and (aminoethylaminomethyl)phenethyltrimethoxysilane (PEDA) Monolayers

For monolayer deposition, silicon wafers were rinsed with acetone and isopropanol, cleaned for 30 min in a UV ozone system, and immersed in boiling deionized water for 5 min to hydrogen-terminate the surface. The wafers were then immersed in solutions containing 50 ml anhydrous methanol, 2 ml water, 2 ml acetic acid, and 1 ml APTS (Pierce Chemical Co.) or PEDA (Gelest, Inc.) for 15 min, then rinsed in methanol (C. S. Dulcey et al., Science, 252, 551 (1991)). Electron exposures were conducted in a scanning electron microscope (LEO Electron Microscopy, Inc.) equipped with a pattern-generating system.

Exposed patterns were examined with lateral-force microscopy (LFM) using a Digital Instruments atomic force microscope. Areas damaged by the electron beam exerted less force on the silicon nitride cantilever than did the neighboring intact areas.

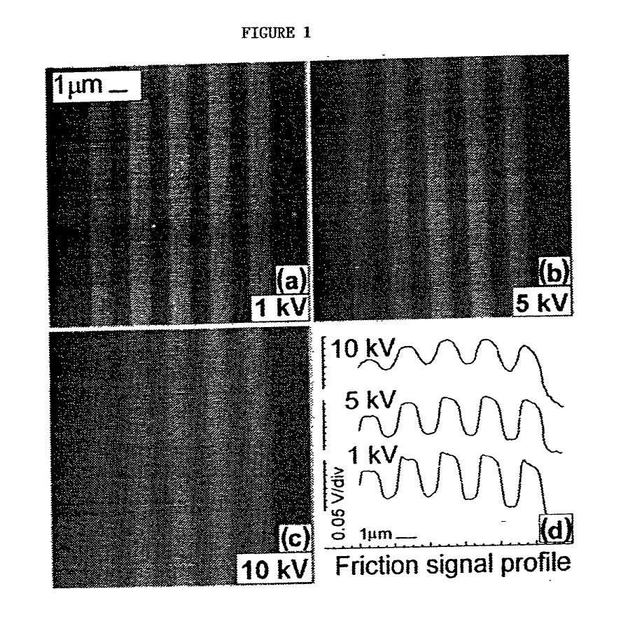

The effect on the SAM of exposures at various electron-beam energies were compared using LFM. The preselected pattern consisted of five 1 μm wide dose bars (100, 200, 300, 400, and 500 μC/cm²), each separated by 1 μm. FIG. 1 shows exposures on APTS using 10, 5, and 1 keV electron-beam energies. The patterns exposed at 1 keV [FIG. 1(a)] and 5 keV [FIG. 1(b)] show sharp 1 μm wide lines, while patterns exposed at 10 keV [FIG. 1(c)] and higher energies are diffuse. FIG. 1(d) is a vertical average of the images, with sharper corners at 1 and 5 keV than at 10 keV. At electron energies of 10-20 keV, backscattered electrons may destroy amine groups outside the exposure area, blurring the lines. At 1 and 5 keV, well-focused 1 μm wide lines could be produced with doses as low as 40 μC/cm².

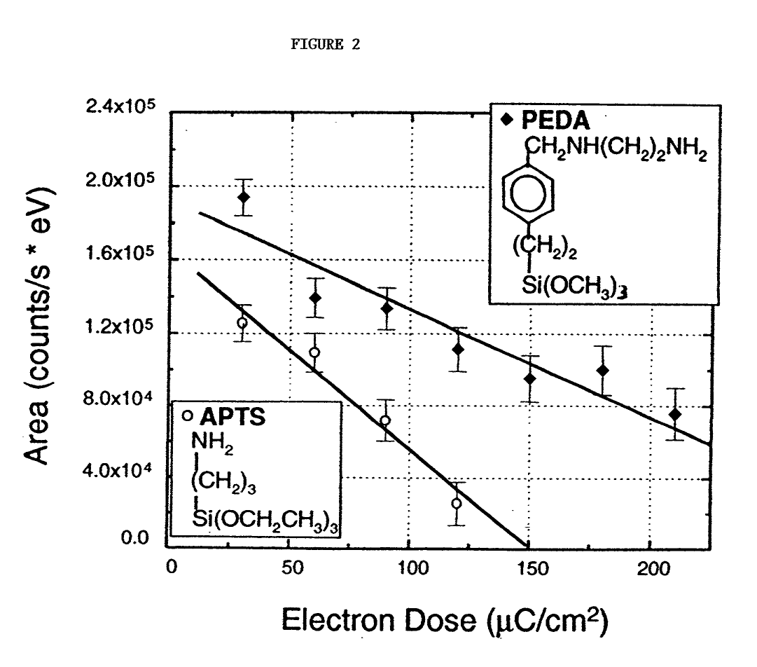

Auger spectroscopy studies showed that electron exposure depletes the monolayer of nitrogen. Nitrogen locations within the monolayers can be seen in the structures of the APTS and PEDA molecules (FIG. 2, insets). APTS contains one amine group at the end, while PEDA has an amine group at the end and a secondary amine group along the molecule's carbon chain.

FIG. 2 shows the area under the nitrogen Auger peak for APTS and PEDA with increasing electron exposure from the Auger instrument. Carbon and oxygen signals remained roughly constant over this range of electron doses. The area under the nitrogen peak decreases at a faster rate for APTS than for PEDA, suggesting that the nitrogen on the end—which should have similar exposure characteristics for both monolayers—is being removed first, while PEDA's secondary nitrogen remains intact longer. This explanation is consistent with previous near-edge x-ray absorption fine structure spectroscopy work on electron-beam damage of methyl-terminated monolayers, which indicated that the end group is damaged before other parts of the molecule. See, H. U. Müller et al., J. Phys. Chem. B., 102, 7949 (1998).

### EXAMPLE 2

### Patterning of Processed SAMs

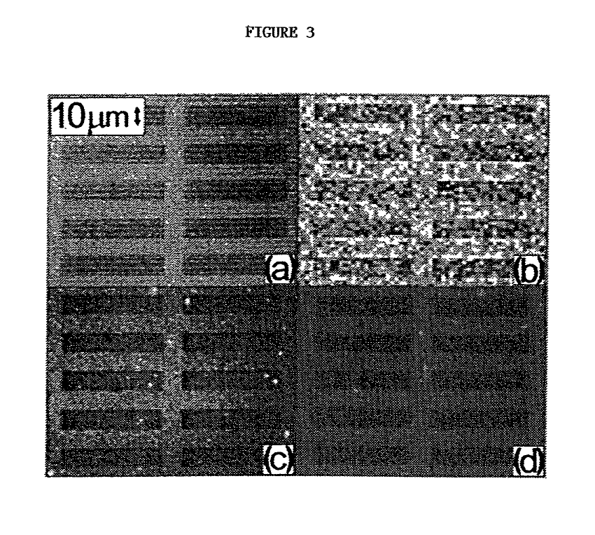

To study subsequent patterning of target substances on SAMs, palladium colloids and two types of coated fluorescent beads (Molecular Probes, Inc.) were reacted with surfaces prepared in accord with Example 1. FIG. 3(a) is a scanning electron microscope image of a PEDA monolayer patterned at 1 keV with a dose of 500 μC/cm², then immersed for 2 min in freshly prepared acidic palladium colloid solution (S. L. Brandow et al., J. Electrochem. Soc. 144, 3425 (1997)). To confirm the adhesion of colloids, an Auger palladium element map was collected over the same area. The map [FIG. 3(b)] shows colloid adsorption onto the unexposed regions. Palladium colloids can be used as a catalyst for further deposition of electroless nickel, silver, or other metals, resulting in films that may be several nanometers thick or more. See, for example, S. L. Brandow, cited above; J. A Rogers et al., Adv. Materials, 9, 475 (1997); D. W. Carr et al., J. Vac. Sci. Technol. A., 15, 1446 (1997).

After electron-beam exposure, some of the substrates were instead immersed for 3 h in a solution of morpholinethanesulfonic acid (MES) buffer containing aldehyde-modified 20 nm polystyrene fluorescent beads. The beads were prepared by mixing 30 μl beads, 3 ml water and 30 μl MES buffer. The solution was sonicated for 5 min and the substrates were immersed in the suspension for 2-3 h. See W. T. Müller et al., Science 268, 272 (1995). The optical fluorescence micrograph in FIG. 3(c) shows that the spheres do not adhere to areas of APTS damaged by the electron beam. Exposure conditions for this SAM were 1 kV accelerating voltage and a dose of 400 μC/cm². No contrast was visible in similar SAMs that were not immersed in fluorescent beads. Doses above 300 μC/cm² produced good contrast in the fluorescence images.

Similar results were obtained using 40 nm fluorescent beads coated with NeutrAvidin protein and dissolved in BlockAid buffer solution (Molecular Probes, Inc.). The buffer solution (3.0 ml) and 30 ml NeutrAvidin coated beads were combined and sonicated for 5 mins. The SAMs were immersed therein for 2-3 h. FIG. 3(d) is a fluorescence micrograph of the protein pattern on APTS with an exposure dose of 300 μC/cm².

### EXAMPLE 3

### Dot-Patterning SAMs

Small-scale protein patterning is necessary to prepare biodevices such as antibody-functionalized diffraction gratings for use in cell detection devices (P. M. St. John et al., Anal. Chem., 70, 1108 (1998)). Electron-beam lithography is a good candidate for building these devices since it is capable of sub-0.1 μm feature sizes that are unreachable by conventional photolithography.

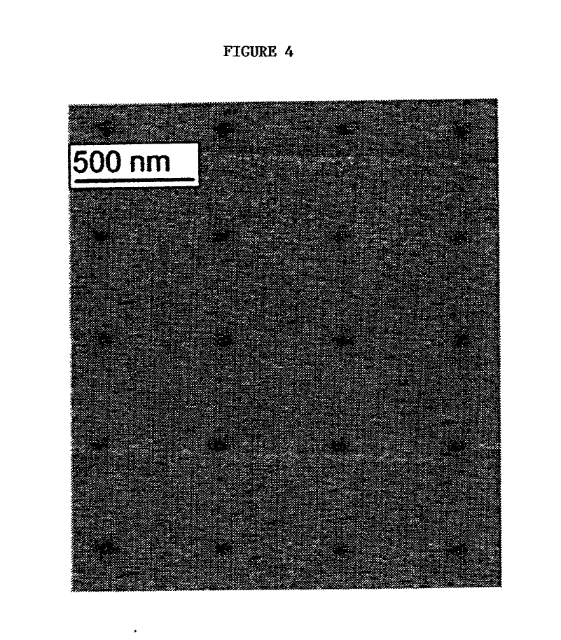

The resolution of low-energy electron-beam patterns on reactive monolayers was studied by patterning small dots in APTS and PEDA. During this study, PEDA was found to have fewer and smaller defects than APTS, which contained voids of approximately 50 mn in diameter, making the dots difficult to resolve against the background. Using 2 kV electrons, 80 nm diam. dots were written using a dose of 5 fC/dot in a PEDA monolayer. The resulting LFM image is shown in FIG. 4. Dot size is limited here by the focus of the electron beam at the low accelerating voltage used to expose the monolayer. Previously, inert octadecyltrichlorosilane monolayers have been patterned with 6 nm dots using a 20 keV beam and a dose of 7 fC/dot (M. J. Lercel et al., Appl. Phys. Lett., 68, 1504 (1996)). These dots approach the size regime of single protein molecules, indicating that the present monolayer templates can be used to position very small quantities of proteins at known locations.

The above examples demonstrate that electron-beam patterned APTS and PEDA monolayers can be used as versatile templates for attachment of other technologically useful materials such as a wide variety of metals and bioactive polypeptides and nucleic acids.

All publications, patents and patent documents are incorporated by reference herein, as though individually incorporated by reference. The invention has been described with reference to various specific and preferred embodiments and techniques. However, it should be understood that many variations and modifications may be made while remaining within the spirit and scope of the invention.

What is claimed is:

1. A method of patterning a self-assembled monolayer (SAM) on a substrate comprising employing low electron-beam lithography to selectively deactivate functional groups at the surface of said SAM in a preselected area of said surface, wherein said functional groups bind to a target substance but said deactivated functional groups do not.

2. The method of claim 1 further comprising contacting said surface of said SAM with said target substance under conditions so that the target substance binds to said functional groups but does not bind to said deactivated groups in said preselected area, to yield a pattern of said target substance on said surface.

3. The method of claim 1 or 2 wherein said functional groups comprise amino groups.

4. The method of claim 3 wherein said SAM comprises organoamines.

5. The method of claim 4 wherein said SAM comprises alkoxysilylorganoamines.

6. The method of claim 1 or 2 wherein the target substance comprises an aldehyde group, a carboxylic acid group, an activated carboxylic acid group or a mixture thereof.

7. The method of claim 1 or 2 wherein said target substance comprises polymeric beads reactive with said functional groups.

8. The method of claim 1 or 2 wherein the target substance comprises a metal.

9. The method of claim 8 wherein the target substance is a metal colloid.

10. The method of claim 9 wherein the metal comprises Pd.

11. The method of claim 10 wherein the target substance comprises a protein.

12. The method of claim 1 wherein the SAM is about 1-2 nm in thickness.

13. The method of claim 1 wherein the electron-beam energy is less than about 5 keV.

14. A substrate comprising a patterned SAM prepared by the method of claim 1.

15. A substrate comprising a patterned target substance on a SAM prepared by the method of claim 2.
